(19) United States
(12) Patent Application Publication
(10) Pub. No.: US 2021/0096415 A1
(43) Pub. Date: Apr. 1, 2021

(54) NARROW BEZEL DISPLAY PANEL AND PREPARATION METHOD THEREOF, AND NARROW BEZEL DISPLAY DEVICE

(71) Applicant: TCL China Star Optoelectronics Technology Co., Ltd., Shenzhen, Guangdong (CN)

(72) Inventor: Kaifeng ZHOU, Shenzhen, Guangdong (CN)

(21) Appl. No.: 16/615,592

(22) PCT Filed: Sep. 20, 2019
(86) PCT No.: PCT/CN2019/106845

§ 371 Date: Nov. 21, 2019

(30) Foreign Application Priority Data
Jul. 8, 2019 (CN) 201910610488.2

(51) Int. Cl. G02F 1/1345; G02F 1/1333; G02F 1/1335

(52) U.S. Cl. CPC G02F 1/13452; G02F 1/133514; G02F 1/133305

(57) ABSTRACT

A narrow bezel display panel and preparation method thereof, and a narrow bezel display device, which can realize transformation between flexibility and rigidity of the base substrate by selecting a flexible photo-curable macromolecule resin material having high light transmittance and by a selective exposure process. A bending region of a base substrate is flexible, and can be bent to hide on a back surface of a base substrate to realize a narrow bezel of the panel; a plane region of the base substrate is rigid, and can remain a stable cell gap during bending.

### FIELD OF INVENTION

The present disclosure relates to field of display technology, and particularly relates to a narrow bezel display panel and preparation method, and narrow bezel display device thereof.

### BACKGROUND OF INVENTION

Liquid crystal displays (LCDs) have advantages, such as energy conservation, lightness and thinness, and exquisite graphics, etc., and have been widely used in the field of display technology. Liquid crystal displays are generally composed of an upper substrate, a bottom substrate, and a liquid crystal layer (LCL) disposed between the two substrates. The upper substrate and the bottom substrate are respectively fabricated. A thin film transistor array (TFT) is disposed on the bottom substrate, and a color filter is disposed on the upper substrate. A liquid crystal cell is formed after the upper substrate and bottom substrate are assembled to each other, and periphery of the liquid crystal cell is sealed using a frame glue. The wider the bezel, the peripheral size of the panel is getting larger, and the actual display area is getting smaller.

In recent years, with continuous development of the liquid crystal display industry and people's demands for liquid crystal display panels are higher and higher, outer bezels of liquid crystal display panels have a tendency to gradually become narrow. For example, TVs and full-screen mobile phones with narrow bezels, by making non-display areas on edges of panels be narrow, thereby increasing the area of the display area and increasing the screen-to-body ratio. The bezels of display panels adopt a more compact and meticulous shape, which makes the product more beautiful. However, present liquid crystal display panels are required to dispose driving arrays and control chips to supply driving voltage to liquid crystal molecules in display areas. Further, driving array are disposed in display areas of panels, and control chips and peripheral circuits such as outer lead bonding (OLB) traces electrically connected to the control chips are disposed on non-display areas of the panels. Therefore, depending on the size of the peripheral circuits, the bezels of the panels are difficult to reduce.

At present, liquid crystal display panels realize narrow bezels primarily in the following ways: 1, designing a narrow bezel sealant, compressing the width of the non-display area, and improving the minimum accuracy of bonding; 2, using side bonding technology to transfer the non-display area to a lateral edge of the bottom substrate. However, the two technical designs and processes are relative difficult and the manufacturing cost is high.

### SUMMARY OF INVENTION

The purpose of the present disclosure is to provide a narrow bezel display panel and a preparation method thereof, and a narrow bezel display device, which can realize an ultra-narrow bezel design requirements while can ensure uniformity of an in-plane cell gap thickness, and the process is compatible with the existing process, and manufacturing cost is low.

In order to realize the purpose mentioned above, the present disclosure provide a narrow bezel display panel. The display panel includes a first substrate and a second substrate disposed opposite the first substrate. The first substrate includes: a base substrate including a plane region and a bending region, and material of the base substrate is a flexible photosensitive-curable macromolecule resin material, and the material is photocured and to be rigid on the plane region, and the material is not photocured to remain flexible on the bending region, and the bending region is bent toward a lateral surface of the base substrate away from the second substrate; at least one driving array disposed on the plane region of the base substrate; and a peripheral circuit disposed on the bending region of the base substrate.

In order to realize the purpose mentioned above, the present disclosure provide a narrow bezel display device, which includes: a narrow bezel display panel, a flexible printed circuit board, and a backlight module; and the narrow bezel display panel including a first substrate, and a second substrate disposed opposite the first substrate; and the first substrate including: a base substrate including a plane region and a bending region, and the base substrate is rigid on the plane region and is flexible on the bending region; at least one driving array disposed on the plane region of the base substrate; and a peripheral circuit disposed on the bending region of the base substrate; the flexible printed circuit board is connected to an outer lead bonding trace layer; the backlight module is disposed on a side of the base substrate away from the second substrate; the bending region is bent toward the backlight module and attached on a lateral surface of the backlight module away from the base substrate.

In order to realize the purpose mentioned above, the present disclosure further provides a preparation method for a narrow bezel display panel. The preparation method including following steps: depositing a sacrificial layer on a glass substrate; making a base substrate on the sacrificial layer, and the base substrate including a plane region and a bending region, and the base substrate is rigid on the plane region and is flexible on the bending region, and the bending region is bent toward the glass substrate; making at least one driving array on the plane region of the base substrate; and making a peripheral circuit on the bending region of the base substrate.

Advantages of the present disclosure are that the present disclosure can realize transformation between flexibility and rigidity of the base substrate by selecting a flexible photo-curable macromolecule resin material having high light transmittance and by a selective exposure process. The bending region of the base substrate is flexible, and can be bent to hide on the back surface of the base substrate, which greatly reduces a width of the display panel to realize a narrow bezel of the display panel; the plane region of the base substrate is rigid, and can remain a stable cell gap when be bent, thereby preventing the cell gap on the plane region from changing, causing uneven display phenomenon (Mura) when the bending region is bent, thereby ensuring the cell gap of the plane region to be uniform. The present disclosure can realize the ultra-narrow bezel design requirement while can ensure uniformity of the in-plane cell gap thickness, and the process is compatible with the existing process, and has advantages of simple manufacturing and low cost.

### DESCRIPTION OF DRAWINGS

To more clearly illustrate the technical solutions of the embodiments of the present disclosure, the accompanying figures of the present disclosure will be described in brief. Obviously, the accompanying figures described below are only part of the embodiments of the present disclosure, from which figures those skilled in the art can derive further figures without making any inventive efforts.

FIG. 1A is a structural schematic diagram of an embodiment of a narrow bezel display panel of the present disclosure.

FIG. 1B is a structural schematic diagram after a bending region of the narrow bezel display panel being bent illustrated in FIG. 1A.

FIG. 2 is a structural schematic diagram of an embodiment of a base substrate of the present disclosure.

FIG. 3 is a structural schematic diagram of an embodiment of a narrow bezel display device of the present disclosure.

FIG. 4 is a flowchart of a preparation method for a narrow bezel display panel of the present disclosure.

FIG. 5A to FIG. 5D are preparation process diagrams of an embodiment of a narrow bezel display panel of the present disclosure.

### DETAILED DESCRIPTION OF PREFERRED EMBODIMENTS

The embodiments of the present disclosure are described in detail hereinafter. Examples of the described embodiments are given in the accompanying drawings, wherein the identical or similar reference numerals constantly denote the identical or similar elements or elements having the identical or similar functions. The specific embodiments described with reference to the accompanying drawings are all exemplary and are intended to illustrate and interpret the present disclosure, which shall not be construed as causing limitations to the present disclosure.

In the present disclosure, unless expressly specified or limited otherwise, a first feature is “on” or “beneath” a second feature may include that the first feature directly contacts the second feature and may also include that the first feature does not directly contact the second feature. Furthermore, a first feature “on,” “above,” or “on top of” a second feature may include an embodiment in which the first feature is right “on,” “above,” or “on top of” the second feature and may also include that the first feature is not right “on,” “above,” or “on top of” the second feature, or just means that the first feature has a sea level elevation higher than the sea level elevation of the second feature. While first feature “beneath,” “below,” or “on bottom of” a second feature may include that the first feature is “beneath,” “below,” or “on bottom of” the second feature and may also include that the first feature is not right “beneath,” “below,” or “on bottom of” the second feature, or just means that the first feature has a sea level elevation lower than the sea level elevation of the second feature.

The following disclosure provides many different embodiments or examples for implementing the different structures of the present disclosure. In order to simplify the disclosure of the present disclosure, the components and configurations of the specific examples are described below. Of course, they are merely examples and are not intended to limit the present disclosure. In addition, the present disclosure may repeat reference numerals and/or reference numerals in different examples, which are for the purpose of simplicity and clarity, and do not indicate the relationship between the various embodiments and/or arrangements discussed. Moreover, the present disclosure provides embodiments of various specific processes and materials, but one of ordinary skill in the art will recognize the use of other processes and/or the use of other materials.

The present disclosure provides a realization method of a new type narrow bezel display panel. A flexible photo-curable macromolecule resin material having high light transmittance is selected on a base substrate of an array substrate, and by a selective exposure process, transformation between flexibility and rigidity of the base substrate can be realized. That is, a bending region of the base substrate is flexible and bendable, and can be bent to hide on the back surface of the base substrate after substrates assembled to each other into a cell and bonding to an external electric circuit, which greatly reduces a width of the display panel to realize a narrow bezel of the display panel. The plane region of the base substrate is rigid, and can remain a stable cell gap when be bent, thereby preventing the plane cell gap from changing and causing uneven display phenomenon (Mura) when the bending region is bent, thereby ensuring the cell gap of the plane region to be uniform. That is, the present disclosure can realize the ultra-narrow bezel design requirement while can ensure uniformity of the in-plane cell gap thickness, and the process is compatible with existing processes, and has advantages of simple manufacturing and low cost.

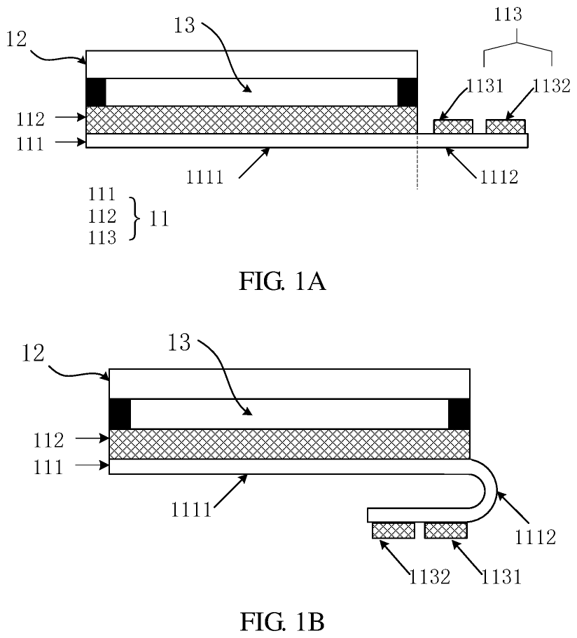

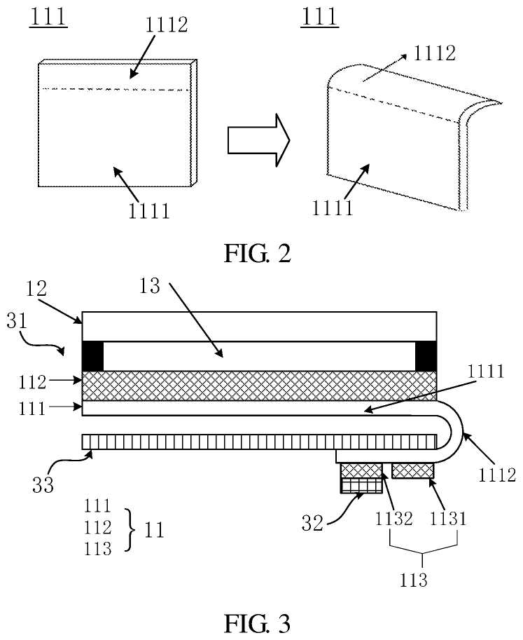

Please refer to FIG. 1A to FIG. 1B, and FIG. 2, FIG. 1A is a structural schematic diagram of an embodiment of a narrow bezel display panel of the present disclosure. FIG. 1B is a structural schematic diagram after a bending region of the narrow bezel display panel being bent illustrated in FIG. 1A. FIG. 2 is a structural schematic diagram of an embodiment of a base substrate of the present disclosure.

As illustrated in FIG. 1A, the display panel includes a first substrate 11 and a second substrate 12. The second substrate 12 is disposed opposite the first substrate 11. The first substrate 11 includes a base substrate 111, at least one driving array 112, and a peripheral circuit 113.

The base substrate 111 includes a plane region 1111 and a bending region 1112, and the base substrate 111 is rigid on the plane region 1111 and is flexible on the bending region 1112. The bending region 1112 can be bent toward a lateral surface of the base substrate 111 away from the second substrate 12. Further, the plane region 1111 corresponds to a region of the display panel for displaying graphics, and the bending region 1112 can be bent toward the back surface of the base substrate, thereby realizing a narrow bezel of the display panel.

In a further embodiment, material of the base substrate 111 is a flexible photosensitive-curable macromolecule resin material, and the material is photocured and to be rigid on the plane region 1111, and the material is not photocured to remain in flexible on the bending region 1112. The bending region 1112 is bendable, and can be bent to hide on the back surface of the base substrate after the substrate assembled to each other into a cell and connected to an external electric circuit, which greatly reduces a width of the display panel to realize a narrow bezel of the display panel. The plane region 1111 can remain a stable cell gap during bending, thereby preventing the plane cell gap from changing when the bending region is bent and causing uneven display phenomenon (Mura), thereby ensuring the cell gap of the plane region to be uniform. Specifically, a characteristic of the material of the base substrate 111 is a highly transparent flexible photosensitive-curable macromolecule resin material such as polyimide (PI), and polydimethylsiloxane (PDMS). The photosensitive-curable macromolecule resin is also known as photosensitive resin, photosensitive macromolecule resin or photoresponsive resin, and which is a polymer material that the chemical change can occur in a short time under the effect of light to cause a change in hardness. A thickness of the base substrate 111 ranges from 0.1 mm to 1 mm, and a transmittance of visible light of the base substrate 111 is greater than 85%. A width of the bending region 1112 ranges from 1 mm to 3 mm. Through a selective exposure process, the plane region 1111 of the base substrate 111 is rigid after exposed the material to be irradiated from light, and as illustrated in FIG. 2, the bending region 112 of the base substrate 111 is not exposed to light to remain ductility to realize to be bent.

The driving array 112 is disposed on the plane region 1111 of the base substrate 111. The driving array 112 is primarily used for supplying voltage to the liquid crystal layer 13 required for driving liquid crystal molecules to deflect.

The peripheral circuit 113 is disposed on the bending region 1112 of the base substrate 111. The peripheral circuit 113 is primarily used for transmitting a driving control signal to the driving array 112 for requirement of displaying. In a further embodiment, the peripheral circuit 113 includes a control chip 1131 (for example, a gate electrode driving chip (gate IC)), and an outer lead bonding (OLB) trace layer 1132 electrically connected to the control chip 1131. The control chip 1131 is used for providing the driving control signal (for example, a scanning signal and/or a data signal, etc.) to the driving array 112, or for receiving signals of the driving array 112 (for example, a fingerprint recognition signal and/or a touch signal, etc.) The control chip 1131 realizes signal transmission by electrically connecting leads of the outer lead bonding trace layer 1132 to an external flexible printed circuit board.

As illustrated in FIG. 1B, after the bending region 1112 being bent, the control chip 1131, the outer lead bonding trace layer 1132 are both bent to the back surface of the base substrate 111 to prevent from occupying the bezel region of the display panel, thereby reducing the width of the bezel of the display panel and increasing the screen-to-body ratio of the display panel.

It should be noted, that the display panel provided by the embodiment is a liquid crystal display panel. The first substrate 11 is an array substrate; the second substrate 12 is a color film substrate; and a liquid crystal layer 13 is disposed between the array substrate and the color film substrate. However, in other embodiments of the present disclosure, the display panel may also be an organic light emitting display panel; the first substrate may be an array substrate; and the second substrate may be a protection cover plate or other cover plate, the present disclosure is not limited herein.

Base on the same invention construct, the present disclosure further provides a narrow bezel display device. Please refer to FIG. 3, it is a structural schematic diagram of an embodiment of a narrow bezel display device of the present disclosure. The narrow bezel display device includes a narrow bezel display panel 31, a flexible printed circuit board 32, and a backlight module 33. The narrow bezel display panel 31 is adopted from the narrow bezel display panel as illustrated in FIG. 1. The flexible printed circuit board 32 is bonded to the outer lead bonding trace layer 1132 of the narrow bezel display panel 31. The backlight module 33 is disposed on a side of the base substrate 111 of the narrow bezel display panel 31 away from the second substrate 12. The bending region 1112 of the narrow bezel display panel 31 is bent toward the backlight module 33, and is attached on a lateral surface of the backlight module 33 away from the base substrate 111.

The flexible printed circuit board 32 is used for electrically connecting the narrow bezel display panel 31 to a mother board of a liquid crystal display device (not shown in figures) to realize signal transmission of the display panel and the mother board. The flexible printed circuit board 32 is bonded to the outer lead bonding trace layer 1132, and the flexible printed circuit board 32 and the control chip 1131 are disposed on the bendable bending region 1112 to prevent from occupying the bezel region of the display panel, thereby reducing the width of the bezel of the display panel and increasing the screen-to-body ratio of the display panel.

The second substrate 12 is disposed opposite the first substrate 11 and corresponds to the plane region 1111. A side of the second substrate 12 away from the liquid crystal layer is a light exiting surface of the display panel. Through bending the bending region having the prepared peripheral circuit to the back surface of the base substrate, the bezel is reduced while will not occupy a space region on the light exiting side of the liquid crystal display panel, so that the liquid crystal display panel and the portion corresponding to the light exiting region of the backlight module can be substantially acted as a region for the liquid crystal display device displaying graphics, the screen-to-body ratio of the liquid crystal display device is further improved, and the backlight utilization ratio of the liquid crystal display device is improved.

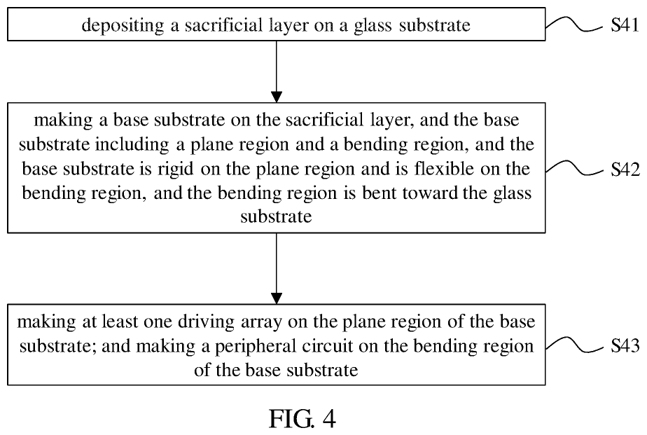

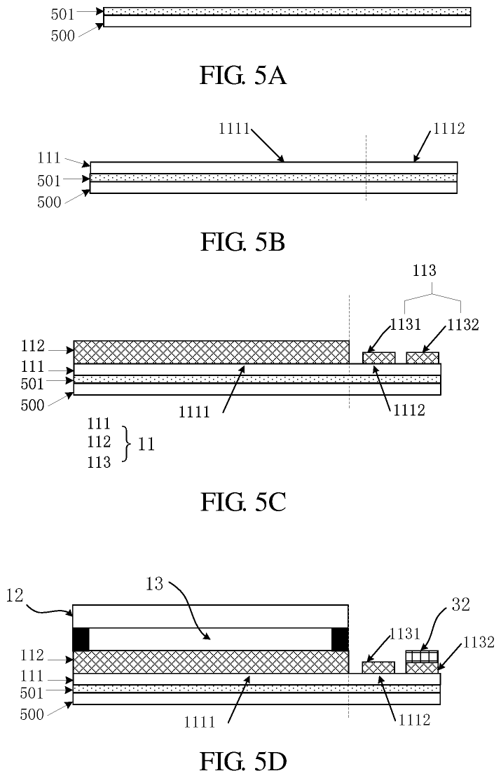

Base on the same invention construct, the present disclosure further provides a preparation method for a narrow bezel display panel. Please refer to FIG. 1, FIG. 3, FIG. 4, and FIG. 5A to FIG. 5D, FIG. 4 is a flowchart of a preparation method for a narrow bezel display panel of the present disclosure, and FIG. 5A to FIG. 5D are preparation process diagrams of an embodiment of a narrow bezel display panel of the present disclosure. The preparation method includes the following steps: S41, depositing a sacrificial layer on a glass substrate; S42, making a base substrate on the sacrificial layer, and the base substrate including a plane region and a bending region, and the base substrate is rigid on the plane region and is flexible on the bending region, and the bending region is bent toward the glass substrate; and S43, making at least one driving array on the plane region of the base substrate; and making a peripheral circuit on the bending region of the base substrate.

About the step S41: depositing a sacrificial layer on a glass substrate, please refer to FIG. 4 and FIG. 5A. As illustrated in FIG. 5A, through depositing the sacrificial layer (CNT/GO) 501 on the glass substrate 500, so that the glass substrate 500 can be peeled off by removing the sacrificial layer 501 in a subsequent process.

About the step S42: making a base substrate on the sacrificial layer, and the base substrate including a plane region and a bending region, and the base substrate is rigid on the plane region and is flexible on the bending region, and the bending region can be bent toward the glass substrate, please refer to FIG. 4 and FIG. 5B. As illustrated in FIG. 5B, the base substrate 111 includes a plane region 1111 and a bending region 1112. The plane region 1111 is primarily used for a region for the display panel displaying graphics, and the bending region 1112 can be bent toward the back surface of the base substrate, thereby realizing the narrow bezel of the display panel. The bending region 1112 is bendable, and can be bent to hide on the back surface of the base substrate after the substrates assembled to each other into a cell and connected to an external electric circuit, which greatly reduces a width of the display panel to realize a narrow bezel of the display panel. The plane region 1111 can remain a stable cell gap during bending, thereby preventing the cell gap of the plane region from changing and causing uneven display phenomenon (Mura) when the bending region is bent, thereby ensuring the cell gap of the plane region to be uniform.

In a further embodiment, through depositing a flexible photo-curable macromolecule resin material on the sacrificial layer 501, and performing a preset exposure process on the corresponding plane region 1111, can make the base substrate 111 be rigid on the plane region 1111 and remain flexible on the bending region 1112. Specifically, a characteristic of the material of the base substrate 111 is a highly transparent flexible photosensitive-curable macromolecule resin material such as polyimide (PI), and polydimethylsiloxane (PDMS). The photosensitive-curable macromolecule resin is also known as photosensitive resin, photosensitive macromolecule resin or photoresponsive resin, and which is a polymer material that the chemical change occurs in a short time under the effect of light to cause a change in hardness. A thickness of the base substrate 111 ranges from 0.1 mm to 1 mm, and a transmittance of visible light of the base substrate 111 is greater than 85%. A width of the bending region 1112 ranges from 1 mm to 3 mm. For example, PI or PDMS can be coated on the sacrificial layer 501, adopting ultraviolet ozone photolysis oxidation technique (UV/O₃) to perform a exposure process on the plane region 1112 (for example, adopting UV/O₃ with 173 nm to expose to light at 20 minutes) and to perform a light shielding protection on the bending region; the material of the plane region 1111 is rigid after being exposed to light, and the material of the bending region 1112 is not exposed to light to remain in flexible and can realize to be bent.

About the step S43: making at least one driving array on the plane region of the base substrate; and making a peripheral circuit on the bending region of the base substrate, please refer to FIG. 4 and FIG. 5C. As illustrated in FIG. 5C, the driving array 112 is prepared on the plane region 1111 of the base substrate 111, and it is primarily used for supplying voltage to the liquid crystal layer 13 driving liquid crystal molecules to deflect. The peripheral circuit 113 is prepared on the bending region 1112 of the base substrate 1111, and it is primarily used for transmitting a driving control signal to the driving array 112 for requirement of displaying. The process is consistent with existing processes, that is, the process of the present disclosure is compatible with the existing process, and has advantages of simple manufacturing and low cost.

In a further embodiment, the peripheral circuit 113 includes a control chip 1131 (for example, a gate electrode driving chip (gate IC)), and an outer lead bonding trace layer (OLB) 1132 electrically connected to the control chip 1131. The control chip 1131 is used for providing the driving control signal (for example, a scanning signal and/or a data signal, etc.) to the driving array 112, or for receiving signals of the driving array 112 (for example, a fingerprint recognition signal and/or a touch signal, etc.) The control chip 1131 is prepared on the bendable bending region 1112 to prevent from occupying the bezel region on the display panel, thereby reducing the width of the bezel of the display panel and increasing the screen-to-body ratio of the display panel.

So far, the first substrate 11 of the display panel is prepared.

When the display panel is a liquid crystal display panel, it is required to assemble a second substrate 12 and the first substrate 11 to each other into a cell, and to bond a flexible printed circuit board 32 with the outer lead bonding trace layer 1132, as illustrated in FIG. 5D, the process is consistent with existing processes. The flexible printed circuit board 32 is used for electrically connecting the display panel to a mother board of a liquid crystal display device to realize signal transmission of the display panel and the mother board. The control chip 1131 and the flexible printed circuit board 32 are electrically connected through leads of the outer lead bonding trace layer 1132 to realize signal transmission between the control chip 1131 and the flexible printed circuit board 32. The flexible printed circuit board 32 is bonded to the outer lead bonding trace layer 1132, and the flexible printed circuit board 32 and the control chip 1131 are disposed on the bendable bending region 1112 to prevent from occupying the bezel region of the liquid display panel, thereby reducing the width of the bezel of the liquid display panel and increasing the screen-to-body ratio of the liquid display panel.

Then, the glass substrate 500 may be peeled off, and a backlight module 33 is disposed on a side of the base substrate 111 away from the second substrate 12; and the bending region 1112 of the base substrate 111 is bent toward a lateral surface of the base substrate 111 away from the second substrate 12, and is attached to a lateral surface of the backlight module 33 away from the base substrate 111 to form the liquid crystal display device. The structure is illustrated as FIG. 3, and the processes of peeling off the glass substrate and disposing the backlight module is consistent with existing processes. Through bending the bending region prepared with the peripheral circuit to the back surface of the base substrate, the bezel is reduced while will not occupy a space region on the light exiting side of the liquid crystal display panel, so that the liquid crystal display panel and the portion corresponding to the light exiting region of the backlight module can be substantially acted as a region for the liquid crystal display device displaying graphics, the screen-to-body ratio of the liquid crystal display device is further improved, and the backlight utilization ratio of the liquid crystal display device is improved.

The subject matter of the present disclosure can be manufactured and applied in the industry and has industrial applicability.

What is claimed is:

1. A narrow bezel display panel comprising: a first substrate, and a second substrate disposed opposite the first substrate; the first substrate comprising:
a base substrate comprising a plane region and a bending region, wherein material of the base substrate is a flexible photosensitive-curable macromolecule resin material, and the material is photocured to be rigid on the plane region, and the material is not photocured to remain flexible on the bending region, and the bending region is bent toward a lateral surface of the base substrate away from the second substrate; at least one driving array disposed on the plane region of the base substrate; and
a peripheral circuit disposed on the bending region of the base substrate.

2. The display panel as claimed in claim 1, wherein a thickness of the base substrate ranges from 0.1 mm to 1 mm.

3. The display panel as claimed in claim 1, wherein a visible light transmittance of the base substrate is greater than 85%.

4. The display panel as claimed in claim 1, wherein the peripheral circuit comprises a control chip, and an outer lead bonding trace layer electrically connected to the control chip.

5. The display panel as claimed in claim 1, wherein the first substrate is an array substrate, the second substrate is a color film substrate, and a liquid crystal layer is disposed between the array substrate and the color film substrate.

6. A narrow bezel display device comprising: a narrow bezel display panel, a flexible printed circuit board, and a backlight module; the narrow bezel display panel comprising a first substrate, and a second substrate disposed opposite the first substrate; and the first substrate comprising: a base substrate comprising a plane region and a bending region, and the base substrate is rigid on the plane region and is flexible on the bending region; at least one driving array disposed on the plane region of the base substrate; and
a peripheral circuit disposed on the bending region of the base substrate; the flexible printed circuit board is connected to an outer lead bonding trace layer; the backlight module is disposed on a side of the base substrate away from the second substrate; the bending region is bent toward the backlight module and attached on a lateral surface of the backlight module away from the base substrate.

7. The display device as claimed in claim 6, wherein material of the base substrate is flexible photosensitive-curable macromolecule resin material, and the material is photocured and to be rigid on the plane region, and the material is not photocured to remain flexible on the bending region.

8. The display device as claimed in claim 7, wherein a thickness of the base substrate ranges from 0.1 mm to 1 mm.

9. The display device as claimed in claim 7, wherein a visible light transmittance of the base substrate is greater than 85%.

10. The display device as claimed in claim 6, wherein the peripheral circuit comprises a control chip, and the outer lead bonding trace layer electrically connected to the control chip.

11. The display device as claimed in claim 6, wherein the first substrate is an array substrate, the second substrate is a color film substrate, and a liquid crystal layer is disposed between the array substrate and the color film substrate.

12. A preparation method for a narrow bezel display panel comprising: depositing a sacrificial layer on a glass substrate; making a base substrate on the sacrificial layer, and the base substrate comprising a plane region and a bending region, and the base substrate is rigid on the plane region and is flexible on the bending region, and the bending region is bent toward the glass substrate; making at least one driving array on the plane region of the base substrate; and making a peripheral circuit on the bending region of the base substrate.

13. The preparation method as claimed in claim 12, wherein making the base substrate on the sacrificial layer further comprises: depositing a flexible photo-curable macromolecule resin material on the sacrificial layer, and performing a preset exposure process on the corresponding plane region, making the base substrate is rigid on the plane region and is flexible on the bending region.

14. The preparation method as claimed in claim 12, wherein a thickness of the base substrate ranges from 0.1 mm to 1 mm.

15. The preparation method as claimed in claim 12, wherein a visible light transmittance of the base substrate is greater than 85%.

16. The preparation method as claimed in claim 12, wherein the peripheral circuit comprises a control chip, and an outer lead bonding trace layer electrically connected to the control chip.
